(19) United States
(12) Patent Application Publication
(10) Pub. No.: US 2026/0169097 A1
(43) Pub. Date: Jun. 18, 2026

(54) MONITORING DEVICE AND METHOD FOR MONITORING THE WEAR CONDITION OF AN ELECTRICAL LINE

(71) Applicant: IGUS GMBH, Cologne (DE)

(72) Inventor: Richard HABERING, Cologne (DE)

(21) Appl. No.: 19/127,080

(22) PCT Filed: Oct. 19, 2023
(86) PCT No.: PCT/EP2023/079077

§ 371 Date: May 2, 2025

(30) Foreign Application Priority Data
Nov. 7, 2020 (DE) 10 2022 129 387.4

(51) Int. Cl. G01R 31/59

(52) U.S. Cl. CPC G01R 31/59

(57) ABSTRACT

The invention relates to a device (11) and a method for monitoring the wear condition of an electrical line (13) which is guided through a movable line guide device, in particular an energy chain (1). According to the invention, the monitoring device (11) is modular, wherein at least an evaluation unit (30), a signal unit (32) and an interface (24A, 24B) are incorporated in a module housing (21) and the module housing (21) has a display (20) for graphical and/or alphanumeric information display, which is arranged on or in the module housing (21) in order to display information about the wear condition.

The invention relates generally to a solution for condition monitoring of one or more electrical lines which are used to transmit data and/or electrical energy. The invention relates in particular to wear condition monitoring of an electrical line which is guided within or through a dynamic or movable line-guiding apparatus.

Dynamic line-guiding apparatuses such as energy guiding chains are used for guiding at least one line, for example a data cable or energy cable, between two connection points, one of which is movable relative to the other, and are known per se.

The lines guided in these apparatuses are heavily stressed inter alia owing to the typically high number of movement cycles.

Irrespective of the type of construction of the line-guiding apparatus or energy guiding chain, the guided lines are subject to dynamic load during operation. The lines are subject to inevitable wear and are therefore at risk of failure as the number of movement cycles performed increases. Therefore, specifically in the case of movably guided lines, there is a demand to monitor the aging condition of the electrical line that arises from inevitable wear.

The generic monitoring systems or monitoring devices in this case are not measuring devices per se, because they are not designed primarily for quantitative ascertainment of physical variables by accurate measurement, or are not intended for this purpose. They are rather monitoring apparatuses which are intended and configured to make predictive maintenance possible in industrial applications, for example in order to prevent inevitable failures, and which are thus intended to make it possible in particular to qualitatively identify a deteriorating line condition or wear condition.

Failures of lines can lead to downtimes resulting from failure of the machine or plant to which a feed is being provided, along with associated high costs. Generic monitoring solutions are used to prevent such failures.

Solutions for condition monitoring of one or more electrical lines have already been proposed by the applicant itself in WO 2018/196949 A1 and in WO 2020/104491A1.

In the solution according to WO2018/196949 A1, line quality monitoring is performed indirectly by means of a representative, special measurement line or by means of dedicated measurement wires which are integrated into the line to be monitored and which serve exclusively for monitoring purposes. It is thus possible to utilize particularly simple technology such as resistance or conductance monitoring.

The solution from WO 2020/104491 A1 does not require any separate measurement wires and is intended specifically for lines for data transmission, such as Ethernet lines. This solution proposes the use of an information-based quality feature of the data transmission, for example a protocol-inherent feature.

A further solution for ascertaining the condition of an electrical line has been proposed for example in EP 3 715 880 A1. For the purposes of ascertaining the condition of an electrical line, said document proposes the application of special measurement pulses to the line during useful operation, with reflected signal components therefrom then being evaluated in order to identify an associated reflection point, on the basis of which it is sought to draw conclusions regarding the condition of the electrical line. Here, the measurement pulses should be applied in time intervals between data packets of the useful signal.

In principle, all of the aforementioned solutions allow monitoring during the ongoing operation of the line. Owing to the industrial application environment, for example, the evaluation or at least the transmission of information to the system user typically takes place at a location remote from the line or application to be monitored, for example at a plant control panel, a process control station or a similar central location. For example, EP 3 715 880 A1 proposes that the device be connected to a centralized computer in which parts of the processes are executed, and acquired data are stored.

A further solution for line monitoring for the purposes of condition monitoring of an electrical line that is subject to movement loads has been proposed in WO 2012/061979A1. The monitoring device proposed in WO 2012/061979 A1 is based on a principle similar to but simpler than that in EP 3 715 880 A1. Said monitoring device comprises a test signal generator, a filter which extracts a check signal generated from the test signal, and an evaluation unit having at least one comparator which compares the check signal with a reference value in order to output a warning signal if a threshold value is overshot.

Proceeding from the known prior art, it is therefore an object of the present invention to propose a solution for condition monitoring of at least one electrical line, which solution noticeably improves user-friendliness in particular for maintenance personnel. The solution should in particular assist in implementing the quickest and most targeted maintenance possible, in particular predictive maintenance.

This is achieved by means of a monitoring device according to claim 1, a monitoring system according to claim 10, and a method according to claim 11. Preferred embodiments can be found in the subclaims.

Proposed is an apparatus or a device for monitoring the wear condition of an electrical line, in particular of a line which is guided through a dynamic or movable line-guiding apparatus, for example through an energy guiding chain. The monitoring apparatus or device comprises, in particular, the following:
a signal unit which is intended and configured for transmitting, processing and/or evaluating signals, wherein the signals are transmitted by an electrical line to be monitored, and wherein the signals may in particular also be normal useful signals; and
an evaluation unit which interacts with the signal unit and is intended and configured to ascertain at least one item of information relating to the wear condition of the line to be monitored, in particular on the basis of transmission, processing and/or evaluation by the signal unit.

In particular, for the purposes of connection to the line, at least one interface, in particular a physical connection, is provided, by means of which the signal unit is connectable to the line to be monitored.

According to the invention, it is proposed that the monitoring device is of modular design and has at least the evaluation unit, the signal unit and the interface combined in a module housing, and that the monitoring unit or module housing also has a display for in particular graphically and/or alphanumerically displaying information.

By means of the display, information relating to the wear condition can be displayed to maintenance personnel on site, on or in the monitored plant or machine. For example, a maintenance instruction based on the at least one item of condition information may in this case be displayed directly on the monitoring module or monitoring device, without the need for a connection to a further device such as a portable computer or the like.

A major advantage consists in that, at least after being set up, possibly via servers, the monitoring device forms a module that is autonomous with regard to the information required for maintenance purposes, which module can display relevant maintenance information to the user independently, without a superordinate computer or the like. This increases user-friendliness, avoids delay in ascertaining relevant information, and can offer redundancy, for example in the event of a failure of the connection to the superordinate computer.

The display is particularly preferably designed to display information in a pixel-based format, in particular is designed as a TFT display, LC display and/or OLED display or the like, in order to be able to display a wide variety of different forms of relatively complex information in selectable formats or languages.

In a preferred embodiment, the display is controlled by the evaluation unit. The evaluation unit may control the display in particular for the purposes of displaying image data in a pixel-based format and/or via a preferably serial IC interface, for example via I2C or the like.

In a particularly preferred combination with the display, a programmable integrated circuit, in particular a microcontroller or microprocessor or the like, for example a DSP, FPGA etc., is provided as an evaluation unit. This allows a high degree of flexibility with regard to the basic settings or the uploading of optional firmware for monitoring different types of lines and the display of correspondingly adapted or selectable information on the display. The programmable integrated circuit particularly preferably comprises a nonvolatile memory, in particular for storing firmware and the like.

The signal unit in turn may, in particular if a data line is to be monitored, comprise a data transmission transceiver, in particular an Ethernet transceiver, preferably having a TDR-based line diagnostic function. There are commercially available transceivers which, for the purposes of identifying faults in the system installation, have TDR checking functions for example in order to check correct line terminations, lengths and other parameters. Such TDR-based line diagnostic functions can advantageously be utilized to allow and/or assist in implementing ongoing condition monitoring.

In one refinement, the module, in particular the evaluation unit, is preferably configured to identify a defect in the monitored line, ascertain a distance to the identified defect and display the ascertained distance by means of the display. For this purpose, use may for example be made of a TDR-based line diagnostic function as described in the introduction with regard to EP 3 715 880 A1.

In addition or alternatively, the module, in particular the evaluation unit, is preferably configured to ascertain a transmission quality on the basis of transmission, processing and/or evaluation by the signal unit and display the ascertained transmission quality by means of the display. For this purpose, use may for example be made of an information-based quality feature of the data transmission, preferably using at least one protocol-inherent function, as is implemented for example on the data security layer of the OSI model, as proposed in WO 2020/104491A1.

The module, in particular the evaluation unit, may furthermore preferably be configured to ascertain a failure cause on the basis of transmission, processing and/or evaluation by the signal unit and display the impending or identified failure cause by means of the display. Here, it can for example be identified whether the deterioration of the line quality is owing to damage to the line, which changes line properties per se, or is caused for example by terminal plug connectors that have degraded.

In a preferred refinement, the monitoring device, in particular the evaluation unit, comprises a web server and an interface, preferably a wireless interface, in particular radio interface, for communication with the web server. The evaluation unit may preferably be configured for parameterization and/or for the purposes of data exchange via the web server. For example, it is also possible for an update to the firmware to be carried out, or for an initialization to be carried out with reference values from a database comprising line-specific parameters. In particular, it is also possible here for the form of presentation on the display to be selectably set, for example in terms of the content to be displayed and/or the format or language thereof, etc.

For the monitoring of one or more data lines, the monitoring device preferably has at least two physical line connections, in particular two control line or data line connections, such as RJ45 connections, DriveClique connections, M23 circular plug connections or the like. Here, the signal unit may communicate or be connected via suitable interfaces, in particular Ethernet interfaces, with or to the connections for the purposes of signal transmission, in particular data transmission.

For increased user-friendliness, the module or monitoring device may have not only the display but also a number of signal lamps for indicating a condition and/or status, for example in the form of a traffic light display indicating a good line condition (“green”), a line condition in need of maintenance (“orange” or “yellow”) and a critical or failed line condition (“red”), the signal lamps additionally being arranged on or in the module housing adjacently to the display. Such signal lamps can then provide an indication as to whether the module or monitoring unit is operating functionally.

In one practical embodiment, the module housing has a front side, in particular a front side which is formed as a narrow side and on which the display is arranged, and a rear side having a fastening device, wherein the display preferably has a width: height ratio≥2:1, and is for example arranged with its longitudinal axis parallel to the length of the narrow side. This allows, inter alia, a compact design.

For industrial applications, it is particularly advantageous for the module to be installed in a switchgear cabinet or the like, as is common in the case of industrial plants or machines. For this purpose, the module preferably has the fastening device on the rear side of the module housing, in the form of a latching fastening for mounting on a DIN/top-hat rail. It is also advantageous if the module housing is of compact design, for example is substantially cuboidal, and is dimensioned in particular for installation in a switchgear cabinet, wherein the front side preferably has dimensions of H×W≤180 mm×60 mm, such that a relatively small width is taken up in the switchgear cabinet.

The proposed solution is suitable for monitoring during the ongoing operation of moving lines, in particular data lines, on or in industrial machines and plants, i. e., during the intended use of the line. The proposed monitoring module is suitable in particular for use in an industrial system, in particular a system having an industrial robot, comprising an electrical line to be monitored, a movable line-guiding apparatus, in particular energy guiding chain, for guiding the line between a first connection point and a second connection point which is movable relative to the first connection point, in particular on an industrial robot, and a module according to the invention or monitoring unit which is connectable to the electrical line to be monitored. Here, the electrical line to be monitored may in particular provide a feed to a device on the end effector or on the robot hand of the industrial robot. Owing to the ever-increasing level of automation and the delicate nature of lines on robots, the proposed solution makes it possible, in particular in this application, to achieve a noticeable acceleration and simplification of maintenance and/or to implement targeted preventative maintenance.

According to a further aspect, a method for monitoring the wear condition of an electrical line which is guided through a movable line-guiding apparatus, in particular through an energy guiding chain, is proposed. In the proposed method, a modular monitoring device is used, which is connected to the line to be monitored and which has at least an evaluation unit and a signal unit.

According to the invention, it is proposed that the modular monitoring unit itself has a display and, by means of this display, displays information relating to the wear condition of the line to be monitored.

The method and module may preferably be configured such that that the monitoring of the wear condition is performed as real-time monitoring during the ongoing operation of the line to be monitored, in particular through continuous monitoring of at least one data transmission property of the line to be monitored, wherein an item of information relating to the wear condition of the line to be monitored is preferably firstly displayed by means of the display and secondly transmitted, in particular by the evaluation unit, via an interface to a superordinate system, in particular for the purposes of initiating predictive maintenance.

Displaying the information relating to the wear condition, in particular together with maintenance instructions, on the module and on a superordinate device, for example a central computer, makes on-site maintenance easier, and can allow an improvement in planning and in the deployment of maintenance personnel.

The method and module may preferably be configured such that the monitoring of the wear condition is performed on the basis of an information-based quality feature of the data transmission, preferably using at least one protocol-inherent function, for example on the OSI data security layer level as in WO 2020/104491 A1, and/or on the basis of a TDR line diagnosis of the line to be monitored.

It is particularly preferable if a distance to an ascertained defect, or a defect that has been identified early, is determined, in particular by the signal unit by means of a TDR line diagnostic function, and the ascertained distance is displayed to the user at the display of the module by means of the display. The maintenance personnel can thus targetedly replace that portion of the line in which the impending defect has been identified early, and can if necessary also purposely use a more robust line for further operation.

The modular monitoring unit preferably performs an initialization in which at least one reference value associated with nominal data transmission properties of the line to be monitored, or with new-condition data transmission properties of the line to be monitored, are stored. Said at least one reference value may subsequently used by the modular monitoring device for the monitoring of the wear condition, in particular during ongoing operation, for the purposes of early identification of possible defects. Application-specific monitoring adapted to the line type used and to the line length provided etc. is thus simplified, and laborious manual parameterization of the modular monitoring device is thus substantially avoided.

The proposed solution offers various further advantages. The display may for example make the initialization process easier for the user by displaying, for setup purposes, choices for the type of line to be monitored, other parameters to be selected, and a confirmation of the selection or parameterization after the initialization process. In the case of a monitoring device for monitoring a plurality of lines, the display may also be used to indicate to the maintenance personnel which of the plurality of lines exhibits an impending or identified defect.

Further advantageous features and effects of the invention will be discussed below on the basis of preferred exemplary embodiments, without limiting the general nature of the description given above, and with reference to the appended drawings. In the drawings:

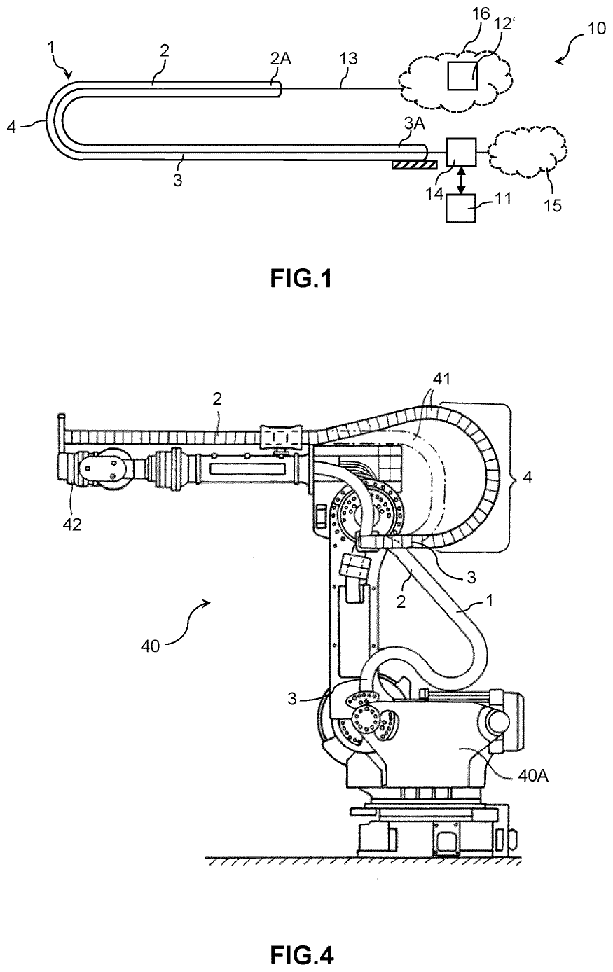

FIG. 1: shows a schematic diagram of a side view of an energy guiding chain having a monitoring system as described generally in WO 2020/104491 A1, in which a monitoring module according to the invention can be used;

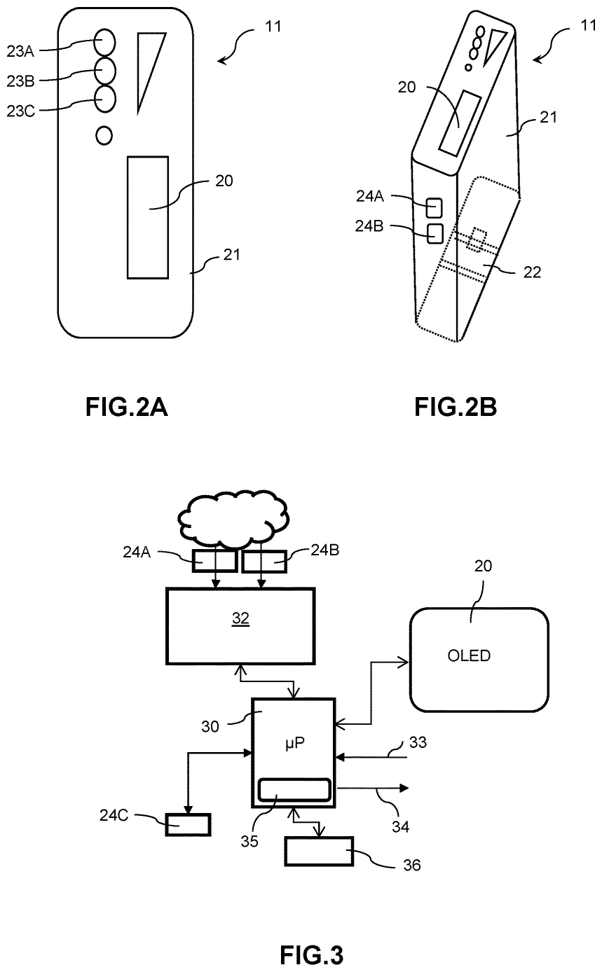

FIG. 2A-2B: show schematic views of a monitoring module according to the invention in a front view and in a perspective view;

FIG. 3: shows a schematic block diagram of a monitoring module according to the invention; and

FIG. 4: shows a side view of an industrial robot having a three-dimensionally deflectable energy guiding chain, which can be equipped with a monitoring module according to FIG. 2-3.

FIG. 1 schematically shows an energy guiding chain 1 as an example of a dynamic line-guiding apparatus. The energy guiding chain 1 serves for the protected guidance of cables, hoses or similar lines, which are not shown in any more detail. Between a moving strand 2, in this case the upper strand, and a static strand 3, in this case the lower strand, the energy guiding chain 1 forms a concomitantly moving deflecting bend 4 with a specified curvature. To avoid line breakages, the deflecting bend 4 has, in particular, a specified minimum radius of curvature, thus ensuring that the admissible radii of curvature of the guided lines are not undershot. The energy guiding chain 1 typically forms an internal guide channel in which an application-dependent number of lines of an application-dependent type are guided.

FIG. 1 shows, purely by way of example, a linearly and horizontally movable energy guiding chain 1. The moving strand 2 ends at a first connection end 2A, for example with an end element which is fastened to a driver of a moving machine part (not shown). The static strand 3 ends at a second connection end 3A, for example with an end element which is fastened to a fixed point of the machine or plant. The deflecting bend 4 follows the movement of the moving connection end 2A, at half the speed. The design of the energy guiding chain 1 is however not crucial to the invention, and use may for example be made of all known energy guiding chains 1 composed of pivotably interconnected individual chain links, even for example three-dimensionally deflectable energy guiding chains as shown in FIG. 4.

FIG. 1 schematically shows, as a main aspect of the system denoted generally by 10 and as a first device, a modular monitoring device 11, hereinafter referred to as monitoring module 11, having an interface for data communication. The monitoring module 11 communicates in particular with a further, second device 12 via its interface for data communication. In the example shown, the devices 11, 12 are configured for data communication, in FIG. 1 for example in accordance with the Ethernet protocol or a protocol similar to or compatible with IEEE 802.3, such as PROFINET, and can thus exchange digital data with one another. The interfaces of the two devices 11, 12 are for this purpose connected via an Ethernet data line 13, for example a conventional CAT 5 data cable with a twisted data line pair (twisted pair). A portion of the length of the data line 13 is, as illustrated in FIG. 1, guided and protected in the line-guiding apparatus or energy guiding chain 1.

The monitoring module 11 comprises not only the ethernet interface for the data line 13 but also at least a signal unit and an evaluation unit, as discussed further below with reference to FIG. 3, which interact in order to ascertain information relating to the condition of the line to be monitored, in this case for example of the data line 13 itself, on the basis of an information-based quality feature of the data connection between the devices 11, 12, in particular using the OSI data security layer.

For the information-based checking of the quality feature of the data connection between the devices 11, 12, use may be made here of a commercially available solution which is suitable for packeted data transmission in accordance with the IP protocol and which, in a protocol-inherent manner, for example using the OSI data security layer, provides for example a function for availability requests, such as an ICMP echo request or a PING message in accordance with the TCP/IP protocol or similar protocol families.

The monitoring module 11 checks the quality of the data connection continuously, for example at regular time intervals, on the basis of the absence of appropriate responses, for example ECHO responses or PONG messages from the second device 12, or else on the basis of changes to the properties of these responses in relation to a reference response. For this purpose, the monitoring module 11 is equipped with suitable software-based functionality and furthermore has a software-based diagnostic function that continuously checks the quality feature in question. In particular, the ascertained number of packet losses may be used as a quality feature, said number being a typical output value from an ICMP echo request or the PING function. If the number of packet losses exceeds a predetermined number, this is indicative in particular of deterioration or breakage of the data line 13 caused by wear or maloperation.

As a second device 12, use may in principle be made of any protocol-compatible network device or any network component which supports the selected protocol function such as availability requests, for example in accordance with the TCP/IP protocol, or which is at least suitable for transmitting acknowledgments to the first device if, for example instead of an Ethernet data connection, use is made of a field bus protocol such as CAN bus, EIA-485 or the like. In the latter case, the monitoring module 11 may for example monitor whether an acknowledgment is received from the second device 12 for every request, and also outputs a warning or fault message if a predetermined error threshold is reached.

The devices 11, 12 of the monitoring device 10 do not cause any significant impairment of the communication between a first region 15 of the data network or of the data bus and a second region 16 of the data network or of the data bus.

As a second device 12 that interacts with the monitoring module 11, use may be made of an application-specific device 12 which is provided in any case in the second region 16 as part of the machine or plant. The further device 12 may for example be inherently configured for responding to an ECHO request or for acknowledging addressed bus data. Therefore, no special second device is required.

For the sake of conciseness, the further teaching from WO 2020/104491 A1, in particular relating to line quality monitoring, is incorporated herein by reference.

An exemplary embodiment according to the invention of the monitoring module 11 will be described in more detail below with reference to FIG. 2A-2B and FIG. 3.

FIG. 2A-2B show schematic views of the housing of the monitoring module 11. The monitoring module comprises, as a essential feature, an integrated display 20, for example an OLED display, for displaying graphical information, said display being provided on the narrow front side of the module housing 21 of the monitoring module. Provided on the averted rear side of the module housing 21 is a latching fastening 22 for mounting on a DIN/top-hat rail, wherein the module housing 21 has compact dimensions, for example H×W×D<180 mm×60 mm×240 mm, and is approximately cuboidal for the purposes of installation in a switchgear cabinet (FIG. 2B). On the front side of the module housing 21 there are provided, inter alia, further status displays for the user in the form of signal lamps 23A, 23B, 23C, which for example indicate the status of the monitored line(s) in accordance with a traffic light principle, such that, if a plurality of monitoring modules 11 are used, it is possible to immediately identify which is indicating an early detection or a fault. For connection to the line, for example the Ethernet data line 13, the module housing 21 has suitable control line or data line connections 24, for example RJ 45 sockets.

A essential functionality of the monitoring module 11 is that of directly displaying information by means of the display 20 directly on the monitoring module 11 or module housing 21.

FIG. 3 illustrates, by way of example, a suitable circuit layout for implementing the monitoring module 11.

The display 20 is controlled, for example via a suitable IC bus, for example an I2C bus, by a programmable microprocessor 30 in order to display image data in a pixel-based format. The microprocessor 30 serves as an evaluation unit, and is connected to and interacts with a signal unit 32, for example a COTS dual port Ethernet transceiver. The signal unit 32, in this case for example in the form of a Ethernet transceiver, is configured for data transmission in accordance with IEEE 802.3 (or in accordance with a similar protocol) and has an integrated line diagnostic function, for example a TDR line diagnostic function. The microprocessor 30 can thus, on the basis of the line diagnostic function of the signal unit 32, ascertain information relating to the wear condition of the line 12 to be monitored.

The signal unit 32 is connected via the connections 24A, 24B to the line 13 to be monitored. Also provided is a diagnostic connection 24C which allows communication with the microprocessor 30 or the application-specific programming thereof. The microprocessor 30 also has an input 33 for one or more manual input devices, for example operator control buttons on the module housing 21 (not shown), and an output 34, inter alia for controlling the signal lamps 23A, 23B, 23C.

The microprocessor 30 in FIG. 3 also has an integrated web server 35 and a radio interface, for example a WLAN interface 36, for communication with the web server 35. The microprocessor 30 is programmed for the purposes of parameterization and/or for the purposes of data exchange through or with a superordinate system via the web server 35.

Interacting with a suitable signal unit 32, the microprocessor 30 may be programmed to
identify a defect in the monitored line 13, ascertain a distance to the identified defect, for example by means of a TDR line diagnostic function of the signal unit 32, and display the ascertained distance by means of the display 20; and/or
ascertain a transmission quality via the line 13 on the basis of protocol-inherent information, for example from the OSI data security layer from the signal unit 32, and display a readout of the ascertained transmission quality by means of the display 20; and/or
ascertain a failure cause on the basis of information from the signal unit 32, in particular on the basis of the line diagnostic function, and display the failure cause by means of the display 20.

By means of the display 20, the modular monitoring device 11 can, on site and in a user-friendly format, display information relating to the wear condition of the line(s) to be monitored.

In terms of function, it should be noted that the monitoring of the wear condition is performed as real-time monitoring during the ongoing operation of the line 13 to be monitored. This may be performed in particular through continuous monitoring of at least one data transmission property. Ascertained information relating to the wear condition of the line 13 to be monitored can firstly be displayed by means of the display 20 and also, in parallel or secondly, transmitted for example via the web server 35 and the radio interface 36 to a superordinate system, which for example initiates predictive maintenance.

The wear condition may be monitored using various technologies, for example using an information-based quality feature of the data transmission, in accordance with the teaching of WO 2020/104491 A1, or for example using the principle of a TDR line diagnosis of the line 13 to be monitored.

The architecture in FIG. 3 also makes it possible for the modular monitoring device 11 to perform an initialization in which at least one reference value associated with nominal signal or data transmission properties of the line to be monitored are stored in a memory of the microprocessor 30. The microprocessor 30 may subsequently use this reference value for the monitoring of the wear condition, in particular during ongoing operation, for the purposes of early identification of possible defects. For example, an onset of deterioration of the transmission properties may be directly used as an indicator for a timely line replacement in order to avoid unplanned plant or machine downtimes.

More detailed information relating to the identified deterioration of the transmission property, and for example the distance to the affected line portion, may be displayed directly on the monitoring module 11 by means of the display 20. Maintenance work on the affected line segment can thus be carried out quickly, targetedly and in a time-saving manner. The aforementioned items of information may also be transmitted, for example via the radio interface 36, to a superordinate system in the context of an IoT solution.

FIG. 4 shows, as an exemplary application for a monitoring system 10 having the monitoring module 11 from FIG. 2-3, an articulated-arm robot 40, for example for the fully automatic handling of workpieces in a manufacturing process. In this case, by way of example, a first linearly movable energy guiding chain 1 leads from the static base 40A of the articulated-arm robot to a rotary joint, from which a three-dimensionally deflectable second energy guiding chain 41 (for example according to WO 2004/093279 A1) continues onward to the end effector 42 or end-side robot tool. On the end effector 42, there are typically a number of actuators and sensors which are already suitable for a conventional field bus protocol, the Ethernet protocol or for example the PROFINET protocol, and which may comprise the communicating second device 12. The address of these field devices or network devices is already known or is predeterminable or programmable. Using the principle from FIG. 1-3, at least one data line or a plurality of data lines which are guided through the energy guiding chains 1, 41 can be monitored with regard to their wear condition. All that is required for this purpose is an inexpensively implementable module 11 according to FIG. 2-3. The proposed monitoring system for monitoring the line condition thus offers an inexpensive solution for assisting in implementing predictive maintenance and/or for reducing or avoiding downtimes. The invention makes it possible inter alia to fully utilize more delicate and possibly also expensive data lines, special lines or the like in terms of their possible service life, i.e., to avoid unnecessarily early replacement.

### LIST OF REFERENCE DESIGNATIONS

### FIG. 1

1 Line-guiding apparatus (energy guiding chain)
2 Moving strand
2A First connection end
3 Static strand
3A Second connection end
4 Deflecting bend
10 Monitoring system
11 Monitoring device (module)
12 Second device
13; 13A, 13B Data line
14 Transmission unit
15 First region (customer network/bus)
16 Second region (customer network/bus)

### FIG. 2A-2B

11 Monitoring module
20 Display (OLED display)
21 Module housing
22 Latching fastening (for DIN rail)
23A, 23B, 23C Signal lamps
24A, 24B Control line and/or data line connections

### FIG. 3

24A, 24B Control line and/or data line connections
24C Diagnostic connection
30 Microprocessor (evaluation unit)
32 Ethernet transceiver (signal unit)
33 Input
34 Output
35 Web server (integrated)
36 Radio interface

### FIG. 4

1 First energy guiding chain (linearly movable)
2, 3 Strands
4 Deflecting bend
40 Articulated-arm robot
40A Base
41 Second energy guiding chain (three-dimensionally deflectable)
42 End effector

1. A monitoring device (11) for monitoring the wear condition of an electrical line (13) which is guided through a movable line-guiding apparatus, in particular through an energy guiding chain (1), the monitoring device comprising:
a signal unit (32) which is configured for transmitting, processing and/or evaluating signals which are transmitted by an electrical line to be monitored;
an evaluation unit (30) which interacts with the signal unit and is configured to ascertain at least one item of information relating to the wear condition of the line to be monitored, in particular on the basis of transmission, processing and/or evaluation by the signal unit;
at least one interface (24A, 24B) by means of which the signal unit is connectable to the line to be monitored;
characterized
in that the monitoring device is of modular design, wherein at least the evaluation unit (30), the signal unit (32) and the interface (24A, 24B) are arranged in a module housing (21); and
in that the module housing (21) has a display (20) for graphically and/or alphanumerically displaying information, said display being arranged on or in the module housing (21) for the purposes of displaying information relating to the wear condition.

2. The monitoring device as claimed in claim 1, characterized in that
the display (20) is designed to display information in a pixel-based format, in particular is designed as a TFT display, LC display and/or OLED display; and/or
the display (20) is controlled by the evaluation unit (30), in particular for the purposes of displaying image data in a pixel-based format and/or via a preferably serial IC interface.

3. The monitoring device as claimed in claim 1 or 2, characterized in that
the evaluation unit (30) comprises a programmable integrated circuit, in particular a microcontroller or microprocessor; and/or
the signal unit (32) comprises a data transmission transceiver, in particular an Ethernet transceiver, preferably having a TDR-based line diagnostic function.

4. The monitoring device as claimed in any one of the preceding claims, in particular as claimed in claim 3, characterized in that the evaluation unit (30) is configured to:
identify a defect in the monitored line (13), ascertain a distance to the identified defect and display the ascertained distance by means of the display (20);
and/or
ascertain a transmission quality on the basis of transmission, processing and/or evaluation by the signal unit (32) and display the ascertained transmission quality by means of the display (20);
and/or
ascertain a failure cause on the basis of transmission, processing and/or evaluation by the signal unit (32) and display the failure cause by means of the display (20).

5. The monitoring device as claimed in any one of the preceding claims, characterized in that the monitoring device, in particular the evaluation unit (30), comprises a web server (35) and preferably a wireless interface, in particular radio interface (36), for communication with the web server, wherein the evaluation unit (30) is preferably configured for the purposes of parameterization and/or for the purposes of data exchange via the web server.

6. The monitoring device as claimed in any one of the preceding claims, characterized in that the monitoring device has at least two physical line connections, in particular two control line and/or data line connections (24A, 24B), wherein the signal unit is connected via interfaces, in particular Ethernet interfaces, to the connections for the purposes of signal transmission, in particular data transmission.

7. The monitoring device as claimed in any one of the preceding claims, characterized in that the monitoring device (11) has not only the display (20) but also a number of signal lamps (23A, 23B, 23C) for indicating a condition and/or status, said signal lamps being arranged on or in the module housing (21) adjacently to the display.

8. The monitoring device as claimed in any one of the preceding claims, characterized in that the module housing (21) has a front side, in particular a front side which is formed on a narrow side and on which the display (20) is arranged, and a rear side having a fastening device (22), wherein the display preferably has a width: height ratio≥2:1.

9. The monitoring device as claimed in claim 8, characterized in that
the fastening device (22) on the rear side of the module housing (21) has a latching fastening for mounting on a DIN/top-hat rail; and/or
the module housing (21) is substantially cuboidal and is dimensioned in particular for installation in a switchgear cabinet, wherein the front side preferably has dimensions of H×W≤180 mm×60 mm.

10. A system, in particular system having an industrial robot (40), comprising an electrical line (13) to be monitored, a movable line-guiding apparatus, in particular energy guiding chain (1; 41), for guiding the line between a first connection point and a second connection point which is movable relative to the first connection point, in particular on an industrial robot, and a monitoring device (11) as claimed in any one of the preceding claims 1 to 9 which is connectable to the electrical line to be monitored, wherein the electrical line (13) to be monitored preferably provides a feed to a device on the end effector (42) or on the robot hand of the industrial robot.

11. A method for monitoring the wear condition of an electrical line which is guided through a movable line-guiding apparatus, in particular through an energy guiding chain, wherein a modular monitoring device is connected to the line to be monitored and has at least an evaluation unit and a signal unit, characterized in that
the modular monitoring unit has a display and, by means of the display, displays information relating to the wear condition of the line to be monitored.

12. The method as claimed in claim 11, characterized in that the monitoring of the wear condition is performed as real-time monitoring during the ongoing operation of the line to be monitored, in particular through continuous monitoring of at least one data transmission property of the line to be monitored, wherein an item of information relating to the wear condition of the line to be monitored is preferably firstly displayed by means of the display and secondly transmitted, in particular by the evaluation unit, via an interface to a superordinate system, in particular for the purposes of initiating predictive maintenance.

13. The method as claimed in claim 11 or 12, characterized in that the monitoring of the wear condition is performed on the basis of
an information-based quality feature of the data transmission, preferably using at least one protocol-inherent function; and/or
a TDR line diagnosis of the line to be monitored.

14. The method as claimed in any one of claims 11, 12 and 13, characterized in that a distance to an ascertained defect is determined, in particular by the signal unit by means of a TDR line diagnostic function, and the ascertained distance is displayed by means of the display.

15. The method as claimed in any one of claims 10 to 14, characterized in that the modular monitoring unit performs an initialization in which at least one reference value associated with nominal data transmission properties of the line to be monitored are stored, and the at least one reference value is subsequently used for the monitoring of the wear condition, in particular during ongoing operation, for the purposes of early identification of possible defects.
